(19) United States
(12) Patent Application Publication
(10) Pub. No.: US 2026/0227207 A1
(43) Pub. Date: Aug. 6, 2026

(54) Non-contact movement sensing device

(71) Applicants: Cheng-Yang Hsu, Tienzhong (TW); Tung-Hung Lu, Tienzhong (TW)

(72) Inventors: Cheng-Yang Hsu, Tienzhong (TW); Tung-Hung Lu, Tienzhong (TW)

(21) Appl. No.: 19/046,316

(22) Filed: Feb. 5, 2025

(51) Int. Cl. G01D 5/20; G01P 15/11

(52) U.S. Cl. CPC G01D 5/20; G01P 15/11

(57) ABSTRACT

A non-contact movement sensing device comprising: a non-conductive member, a plurality of induction coils, and a microprocessor. The non-conductive member is divided into a plurality of regions and an upper surface and a lower surface, and the induction coils are respectively installed on the lower surface corresponding to different regions. The induction coils are capable of generating inductive capacitance, and an electric field of each induction coil extends to the surrounding environment. The microprocessor is connected to the induction coils and includes a capacitive detection chip.

### BACKGROUND OF THE INVENTION

### Field of Invention

The present invention relates to a non-contact movement sensing device, and more particularly to a control switch capable of inducing with current with object movement.

### Description of the Related Art

Currently, conventional human body movement sensing devices such as game controls all use physical switch buttons. While operating, the switch needs to be actually pressed to complete the triggering action.

However, because the current structures all require actual contact, when it is applied to surfaces that may deform, such as silk, elastic surfaces, etc., it will easily cause damage to the switch.

Therefore, it is desirable to provide a non-contact movement sensing device to mitigate and/or obviate the aforementioned problems.

### SUMMARY OF THE INVENTION

An objective of present invention is to provide a non-contact movement sensing device structure, which is capable of improving the above-mention problems.

### SUMMARY OF THE DISCLOSURE

In order to achieve the above-mentioned objective, a non-contact movement sensing device comprising: a non-conductive member, a plurality of induction coils, and a microprocessor. The non-conductive member is divided into a plurality of regions and an upper surface and a lower surface, and the induction coils are respectively installed on the lower surface corresponding to different regions. The induction coils are capable of generating inductive capacitance, and an electric field of each induction coil extends to the surrounding environment; wherein since a human body is conductive and has dielectric and conductive properties, when at least one human body is close to or in contact with one or more of the induction coils, a capacitance value of the entire system changes. The microprocessor is connected to the induction coils and includes a capacitive detection chip, the capacitive detection chip is capable of charging the induction coils; wherein when at least one human body approaches or touches one or more of the induction coils, a capacitance on the one or more induction coils changes significantly, which is then detected by the capacitive detection chip, which sends an analog signal to an analog read pin of the microprocessor, the significant change in capacitance is used to determine whether the human body is making contact so that the induction coil can be used as a switch by presence or absence of a contact signal.

Other objects, advantages, and novel features of invention will become more apparent from the following detailed description when taken in conjunction with the accompanying drawings.

### BRIEF DESCRIPTION OF THE DRAWINGS

FIG. 1 is a three-dimensional combination drawing of a preferred embodiment of the present invention.

FIG. 2 is a three-dimensional exploded view of the preferred embodiment of the present invention.

FIG. 3 is showing a user's hand approaching motion to the induction coil according to the preferred embodiment of the present invention.

FIG. 4 is showing the inductive capacitance generated after the user's hand making contact with the induction coil according to the preferred embodiment of present invention.

FIG. 5 is a drawing showing the induction state according to the preferred embodiment of the present invention.

FIG. 6 is a drawing showing an embodiment of the present invention used in a trampoline.

FIG. 7 is a drawing showing the induction coil in the extended state during the bounce according to the preferred embodiment of the present invention.

FIG. 8 is a drawing showing an embodiment of the present invention in which an acceleration sensor is installed.

FIG. 9 is a state drawing of the magnitude of the bounce force measured by the acceleration sensor according to the preferred embodiment of the present invention of the present invention.

FIG. 10 is a drawing showing an embodiment of the present invention being used for a control panel.

### DETAILED DESCRIPTION of PREFERRED EMBODIMENT

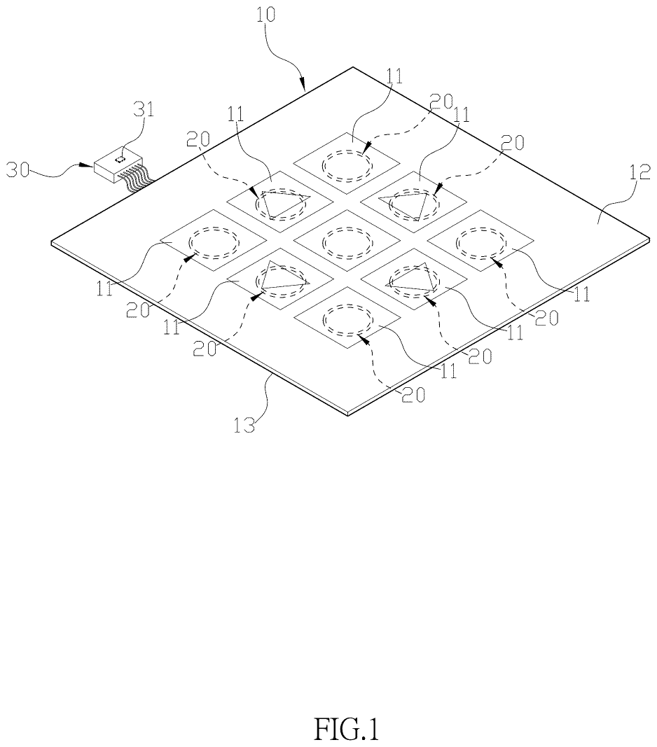

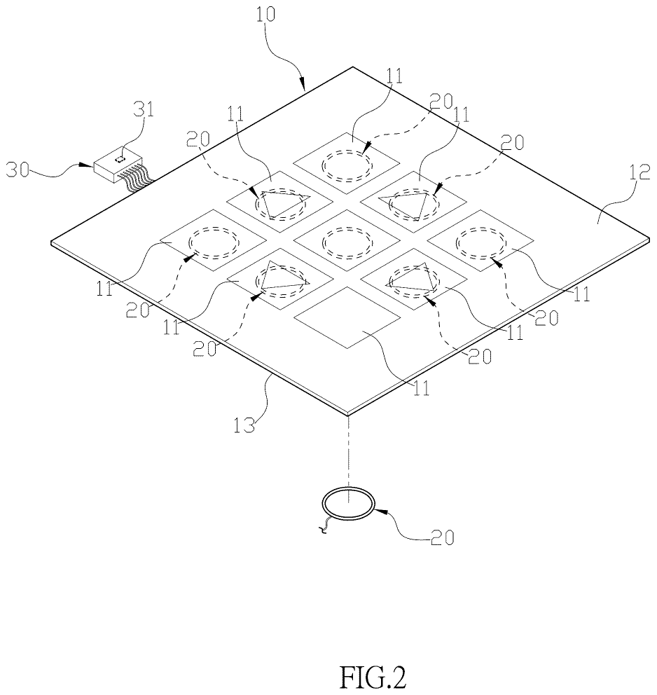

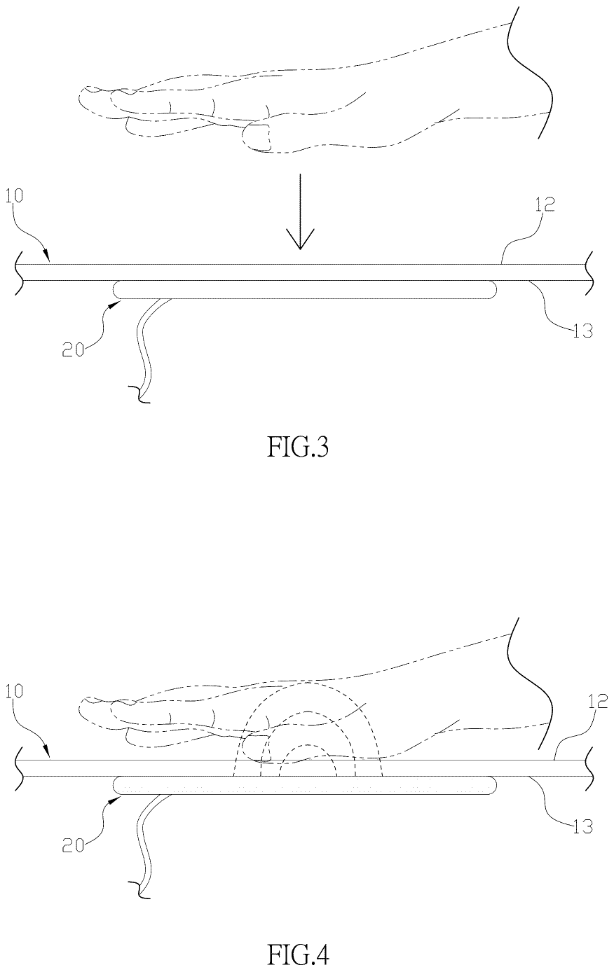

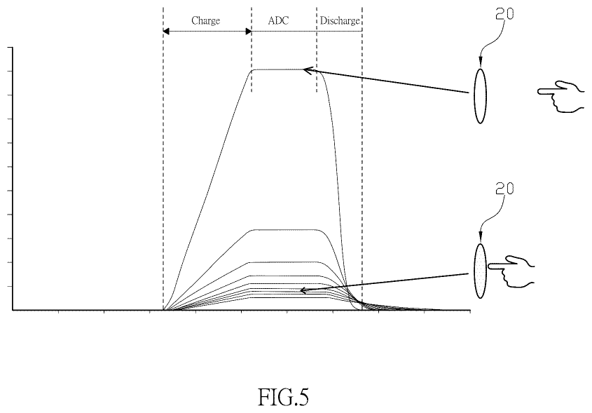

First, please refer to FIGS. 1 and 2. A non-contact movement sensing device comprising non-conductive member 10, a plurality of induction coils 20 and a microprocessor 30. The non-conductive member 10 is divided into a plurality of the region 11 and an upper surface 12 and a lower surface 13, and the induction coil 20 are respectively installed on the lower surface 13 corresponding to different regions 11. The induction coil 20 are capable of generating inductive capacitance, and an electric field of each induction coil extends to the surrounding environment; wherein since a human body is conductive and has dielectric and conductive properties, when at least one human body is close to or in contact with one or more of the induction coils 20, a capacitance value of the entire system changes. The microprocessor 30 is connected to the induction coil 20 and includes a capacitive detection chip 31, the capacitive detection chip 31 is capable of charging the induction coil 20. A capacitance on the one or more induction coils 20 changes significantly (as shown in FIGS. 3-5), which is then detected by the capacitive detection chip 31, which sends an analog signal to an analog read pin of the microprocessor 30, the significant change in capacitance is used to determine whether the human body is making contact so that the induction coil 20 can be used as a switch by presence or absence of a contact signal.

In addition, the non-conductive member 10 is a soft material/

Furthermore, the non-conductive member 10 is an elastic fabric for a trampoline )as shown in FIGS. 1, 2, 6, 7, 8 and 9).

Also, the non-conductive member 10 has a nine-square grid region formed on it, and the nine-square grid region 11 defines functions of up, down, left, and right arrow keys and a space bar (as shown in FIGS. 1, 2, 3 and 6).

Additionally, wherein the non-conductive member 10 is soft silk.

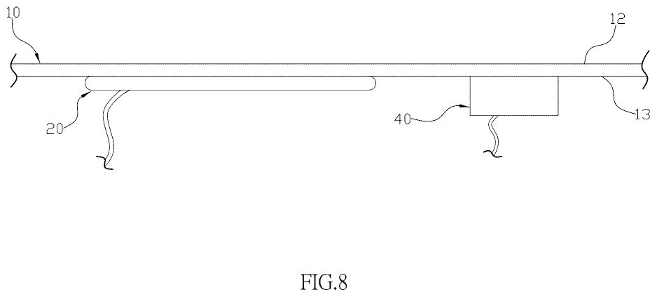

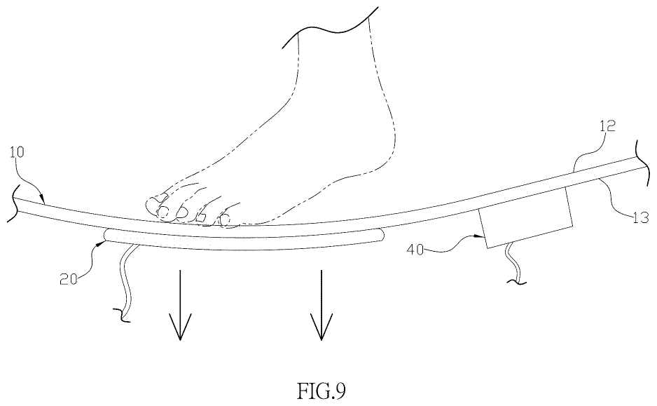

Moreover, the microprocessor 30 is further connected to an acceleration sensor 40, as shown in FIG. 8. When the non-conductive member 10 vibrates, the acceleration sensor 40 reacts accordingly, so that the acceleration value measured by the microprocessor 30 is further converted into the vibration amplitude of the surface of the non-conductive member 10, as shown in FIG. 9.

Furthermore, the non-conductive member 10 is a hard material.

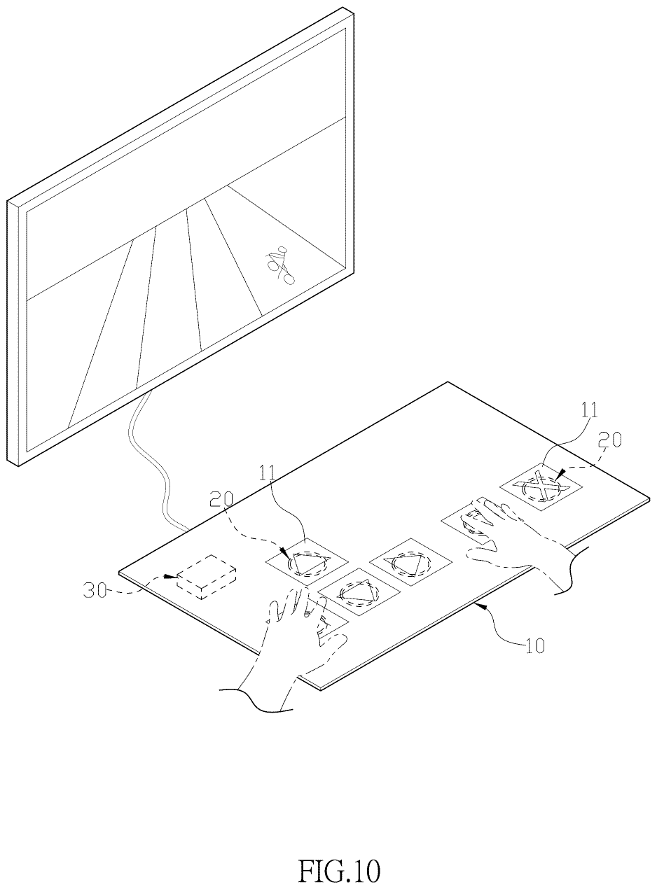

Also, the non-conductive member 10 is a control panel, as shown in FIG. 10.

Alternatively, the non-conductive member 10 is a plastic board.

Optional, the non-conductive member 10 is a wooden board.

Moreover, the non-conductive member 10 is a thick cardboard.

Also, the induction coil 20 is a copper induction coil.

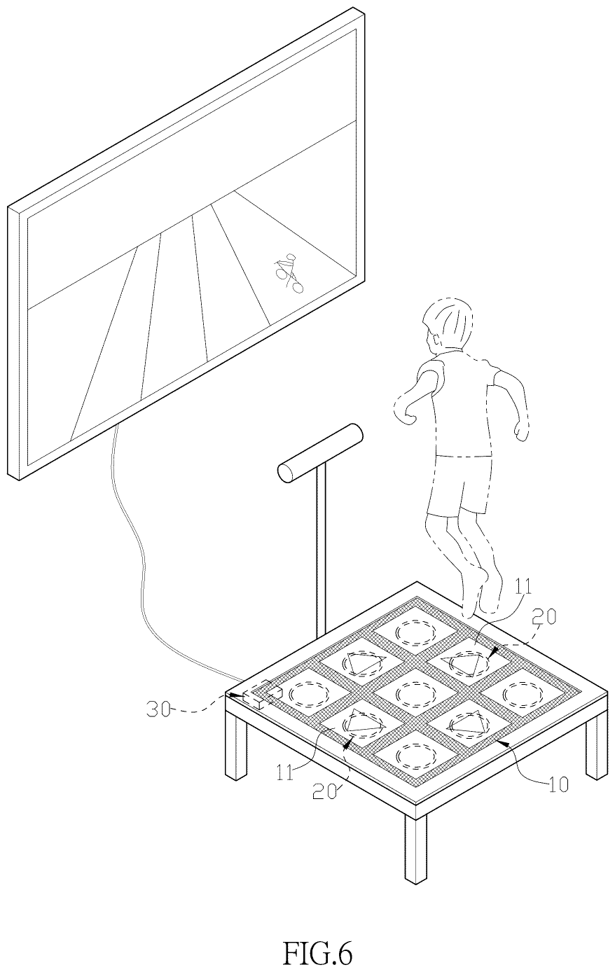

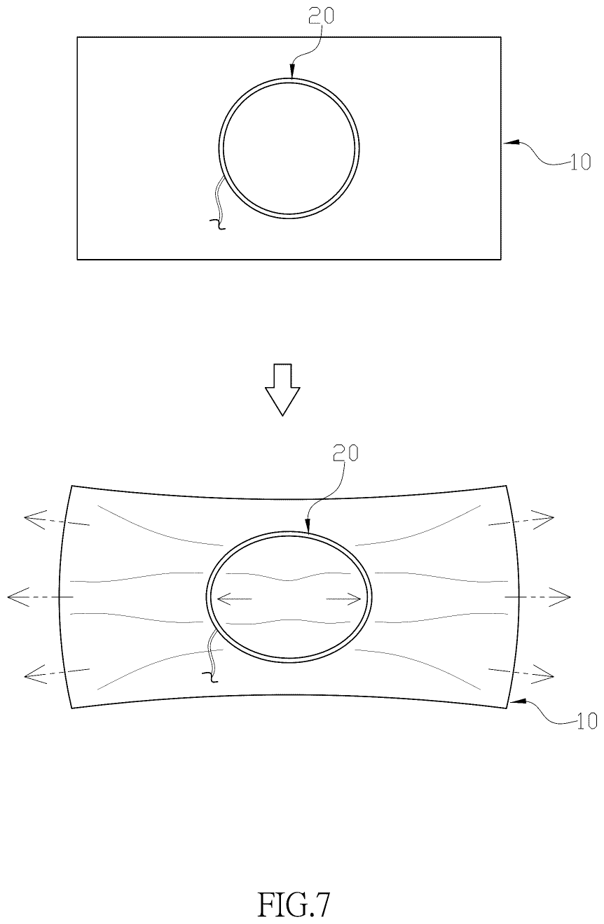

When a user steps into the sensing range of the induction coil 20, an electric field change is generated around the induction coil 20, and the electric field signal can be processed by the microprocessor 30. For example, with the nine induction coils 20 of the trampoline shown in FIG. 6, when the user steps on any of the regions 11, the induction coil 20 installed on the lower surface 13 is activated; in this example, there are nine switches, each of which operates independently. When the user jumps off the upper surface 12 of the non-conductive member 10, i.e., the trampoline surface, the switch is released, and the game content is controlled by changing the switch state. Comparing with traditional physical buttons, the induction coil 20 has better adaptability to the deformation of soft elastic surfaces. As shown in FIG. 7, and within a certain extension range, it is not easy to be damaged by deformation. In addition, by adjusting the sensitivity of the microprocessor 30, the induction distance can be various. When the non-conductive member 10 is equipped with the acceleration sensor 40, the up and down bounces can cause the acceleration sensor 40 to shake, so that the microprocessor 30 can detect the vibration of the acceleration sensor 40 and perform the algorithm calculates to obtain the current bounce force, as shown in FIG. 9.

The non-contact movement sensing device has the following advantages: First, the induction coil 20 is used as the sensing device, and compared with the traditional physical button, the effect of a switch button can be achieved without actually touching the induction coil 20, the induction coil 20 is better adapt to the deformation of soft elastic surface within a certain extension range, and it is not easy to be damaged by deformation and has a long service life. Second, the induction coil 20 can be used under the surface of the various non-conductive materials 10, so it obviously has a low-cost system architecture and the substantial effect of improving user experience, and the induction coil 20 has high reliability and sensitivity.

Although the present invention has been explained in relation to its preferred embodiment, it is to be understood that many other possible modifications and variations can be made without departing from the spirit and scope of invention as hereinafter claimed.

What is claimed is:

1. A non-contact movement sensing device comprising: a non-conductive member, a plurality of induction coils, and a microprocessor; wherein
the non-conductive member is divided into a plurality of regions and an upper surface and a lower surface, and the induction coils are respectively installed on the lower surface corresponding to different regions;
the induction coils are capable of generating inductive capacitance, and an electric field of each induction coil extends to the surrounding environment; wherein since a human body is conductive and has dielectric and conductive properties, when at least one human body is close to or in contact with one or more of the induction coils, a capacitance value of the entire system changes; and
the microprocessor is connected to the induction coils and includes a capacitive detection chip, the capacitive detection chip is capable of charging the induction coils; wherein when at least one human body approaches or touches one or more of the induction coils, a capacitance on the one or more induction coils changes significantly, which is then detected by the capacitive detection chip, which sends an analog signal to an analog read pin of the microprocessor, the significant change in capacitance is used to determine whether the human body is making contact so that the induction coil can be used as a switch by presence or absence of a contact signal.

2. The non-contact movement sensing device as claimed in claim 1, wherein the non-conductive member is a soft material.

3. The non-contact movement sensing device as claimed in claim 1, wherein the non-conductive member is an elastic fabric for a trampoline.

4. The non-contact movement sensing device as claimed in claim 1, wherein the non-conductive member has a nine-square grid region formed on it, and the nine-square grid region defines functions of up, down, left, and right arrow keys and a space bar.

5. The non-contact movement sensing device as claimed in claim 1, wherein the non-conductive member is soft silk.

6. The non-contact movement sensing device as claimed in claim 1, wherein the non-conductive member is a hard material.

7. The non-contact movement sensing device as claimed in claim 1, wherein the non-conductive member is a control panel.

8. The non-contact movement sensing device as claimed in claim 1, wherein the non-conductive member is a plastic board, wood board or cardboard.

9. The non-contact movement sensing device as claimed in claim 1, wherein the induction coil is a copper induction coil.

10. The non-contact movement sensing device as claimed in claim 1, wherein the microprocessor is further connected to an acceleration sensor.
